(19) United States
(12) Patent Application Publication
(10) Pub. No.: US 2025/0319695 A1
(43) Pub. Date: Oct. 16, 2025

(54) MANUFACTURING APPARATUS AND METHOD FOR DISPLAY DEVICE

(71) Applicant: Samsung Display Co., Ltd., Yongin-Si (KR)

(72) Inventors: Yong Woo LEE, Yongin-si (KR); Yeong Jun KIM, Yongin-si (KR); Jeong Hun KIM, Yongin-si (KR); Seung Gun LEE, Yongin-si (KR)

(21) Appl. No.: 19/002,739

(22) Filed: Dec. 27, 2024

(30) Foreign Application Priority Data
Apr. 12, 2024 (KR) 10-2024-0049324

(51) Int. Cl. B41J 2/045; B41J 3/407; G01B 11/06

(52) U.S. Cl. CPC B41J 2/04556; B41J 3/407; G01B 11/0608

(57) ABSTRACT

The present disclosure relates to a manufacturing apparatus and method for a display device. According to an embodiment of the disclosure, a manufacturing apparatus for a display device comprises: a stage including a substrate seating area, which is configured for seating a substrate, and a surrounding area, which is positioned around the substrate seating area; a dispenser positioned above the stage and including a nozzle for discharging ink; and a gap measurement unit positioned at least partially in the surrounding area of the stage. The gap measurement unit includes a reference block and a camera that faces the reference block.

### CROSS-REFERENCE TO RELATED APPLICATION

This application claims priority from Korean Patent Application No. 10-2024-0049324 filed on Apr. 12, 2024 in the Korean Intellectual Property Office, and all the benefits accruing therefrom under 35 U.S.C. 119, the contents of which in its entirety are herein incorporated by reference.

### BACKGROUND

### 1. Field

The present disclosure relates to a manufacturing apparatus and method for a display device.

### 2. Description of the Related Art

With the advancement of the information society, the demand for display devices for displaying images is increasing in various forms. For example, display devices are being applied to various electronic devices such as smartphones, digital cameras, laptop computers, navigation systems, and smart televisions.

Various types of display devices such as liquid crystal display (LCD) and organic light-emitting diode (OLED) display devices are being used.

The manufacture of a display device may involve an application process of applying a sealant, which is a bonding material, to a substrate to bond the substrate with another substrate or another structure.

During the application of the sealant, a dispenser including a nozzle is used to discharge the sealant onto the substrate, and the discharge amount of the sealant can be adjusted according to the gap between the substrate and the nozzle. Therefore, it is important to measure and calibrate the gap between the substrate and the nozzle. However, if the gap calibration is not conducted accurately, the discharge amount of the sealant through the nozzle may become inaccurate, which can cause variations in predefined linewidths and result in variations in application quality, leading to process dispersion.

### SUMMARY

Aspects of the present disclosure provide an apparatus and method for manufacturing a display device, capable of performing gap calibration in a non-contact manner.

According to an embodiment of the disclosure, a manufacturing apparatus for a display device comprises: a stage including a substrate seating area, which is configured for seating a substrate, and a surrounding area, which is positioned around the substrate seating area; a dispenser positioned above the stage and including a nozzle for discharging ink; and a gap measurement unit positioned at least partially in the surrounding area of the stage. The gap measurement unit includes a reference block and a camera that faces the reference block.

In an embodiment, the stage includes: a stage body, which includes the substrate seating area; and an auxiliary frame, which is positioned on one side of the stage body, and the gap measurement unit is disposed to overlap with the auxiliary frame.

In an embodiment, the reference block is positioned on a same plane as the substrate.

In an embodiment, the manufacturing apparatus further comprises: a dispenser vertical driver moving the dispenser vertically relative to the substrate and the reference block, wherein in the surrounding area, the dispenser is raised or lowered vertically between the reference block and the camera by the dispenser vertical driver.

In an embodiment, the manufacturing apparatus further comprises: a storage unit storing a drive value of the dispenser vertical driver based on measurement results of a gap from the camera; and a control unit controlling the dispenser vertical driver to raise and lower the dispenser.

In an embodiment, the measurement results indicate that the gap matches a reference set value, and the control unit stores the drive value of the dispenser vertical driver in the storage unit and moves the dispenser in the surrounding area to the substrate seating area.

In an embodiment, the manufacturing apparatus further comprises a lookup table storing the drive value of the dispenser vertical driver as a data value.

In an embodiment, the manufacturing apparatus further comprising: height adjustment means coupling the auxiliary frame to be adjustable in height relative to the stage body.

In an embodiment, the reference block is disposed on the auxiliary frame at a position apart from the substrate in a first direction, and the camera is positioned behind the reference block in the first direction.

In an embodiment, the manufacturing apparatus further comprises: a base frame supporting the stage from below; a stage transfer unit moving the stage along a first direction; and a dispenser support unit coupling the dispenser to the base frame.

In an embodiment, the reference block has a long bar shape along a second direction perpendicular to the first direction, and a plurality of cameras including the camera are provided along the second direction.

According to an embodiment of the disclosure, a manufacturing method for a display device comprises: positioning a dispenser, including a nozzle, above a display device substrate seated on a stage; moving the dispenser to a gap calibration area, which is positioned along a first direction away from the stage and in which a gap measurement unit with a reference block and a camera is positioned; measuring a gap between an upper surface of the reference block and a tip of the nozzle in the gap calibration area using the camera; and removing the dispenser from the gap calibration area when the gap matches a reference set value based on results of the measuring the gap.

In an embodiment, the manufacturing method further comprises: storing a drive value of a dispenser vertical driver, which moves the dispenser vertically relative to the substrate and the reference block, based on the results of the measuring the gap.

In an embodiment, wherein the removing the dispenser comprises moving the dispenser from the gap calibration area to a discharge position above the substrate.

In an embodiment, the manufacturing method further comprises: ejecting a liquid onto the substrate at the discharge position while raising the dispenser based on the stored drive value.

In an embodiment, the manufacturing method further comprises: additionally measuring the gap during the ejecting the liquid; and additionally storing a drive value of the dispenser vertical driver based on results of the additionally measuring the gap.

According to an embodiment of the disclosure, a manufacturing method for a display device comprises: positioning a dispenser, including a nozzle, above a display device substrate seated on a stage; moving the dispenser to a gap calibration area, which is positioned along a first direction away from the stage and in which a gap measurement unit with a reference block and a camera is positioned; measuring a gap between an upper surface of the reference block and a tip of the nozzle in the gap calibration area using the camera; and calibrating the gap by raising or lowering the dispenser using a dispenser vertical driver based on results of the measuring the gap.

In an embodiment, the manufacturing method further comprises: storing a drive value of the dispenser vertical driver based on the results of the measuring the gap; and moving the dispenser from the gap calibration area to a discharge position above the substrate.

In an embodiment, the manufacturing method further comprises: ejecting a liquid onto the substrate at the discharge position while raising the dispenser based on the stored drive value.

In an embodiment, during the ejecting the liquid, the measuring the gap and the calibrating the gap are repeated at least once.

According to the aforementioned and other embodiments of the present disclosure, gap calibration with excellent reproducibility can be performed in a non-contact manner.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings.

FIG. 1 is a perspective view of a manufacturing apparatus for a display device according to an embodiment.

FIG. 2 is a top view illustrating a substrate, a stage, and a gap measurement unit of FIG. 1.

FIG. 3 is a top view of a manufacturing apparatus for a display device according to an embodiment of the present disclosure.

FIG. 4 is a block diagram of a manufacturing apparatus for a display device according to an embodiment of the present disclosure.

FIG. 5 is a block diagram of a manufacturing apparatus for a display device according to an embodiment of the present disclosure.

FIG. 6 is a flowchart illustrating a gap calibration method for a manufacturing apparatus for a display device, according to an embodiment of the present disclosure.

FIG. 7 is a flowchart illustrating a gap calibration method for a manufacturing apparatus for a display device, according to an embodiment of the present disclosure.

FIGS. 8, 9, 10, 11, 12, 13, and 14 illustrate a gap calibration process according to an embodiment of the present disclosure.

FIGS. 15 and 16 illustrate a gap calibration process according to an embodiment of the present disclosure.

FIGS. 17 and 18 illustrate a gap calibration process according to an embodiment of the present disclosure.

FIGS. 19 and 20 illustrate a gap calibration process according to an embodiment of the present disclosure.

FIG. 21 is a top view illustrating the movement path between a gap calibration area and an ejection area in a manufacturing apparatus for a display device according to an embodiment of the present disclosure.

FIG. 22 is a cross-sectional view of a display device manufactured by the manufacturing apparatus of FIG. 21.

FIG. 23 is a cross-sectional view of a display panel of FIG. 22.

### DETAILED DESCRIPTION

The advantages and features of the inventive concept, and the methods for achieving them, will become apparent by referring to the embodiments described below in detail along with the accompanying drawings. However, the inventive concept is not limited to the embodiments disclosed herein but can be implemented in various forms, and these embodiments are merely provided to make the disclosure of the inventive concept complete and to fully inform those skilled in the art of the scope of the inventive concept.

When referring to an element or layer being “on” another element or layer, it encompasses both cases where the element is directly on top of the other element and where another layer or element is interposed between them. Throughout the specification, the same reference numerals refer to the same components.

Although terms such as “first,” “second,” etc., are used to describe various components, these components are not limited by these terms. These terms are only used to distinguish one component from another. Therefore, a first component may also be referred to as a second component within the technical concept of the inventive concept.

Various features from the embodiments of the inventive concept can be combined or interchanged either partially or as a whole, and various technical interactions and operations are possible. These embodiments may be implemented independently of one another or in association with one another.

Embodiments of the present disclosure will hereinafter be described with reference to the accompanying drawings.

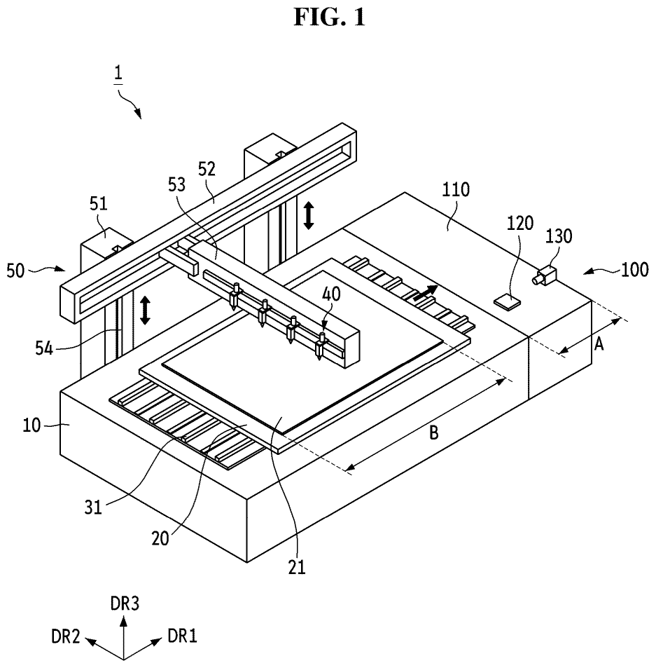

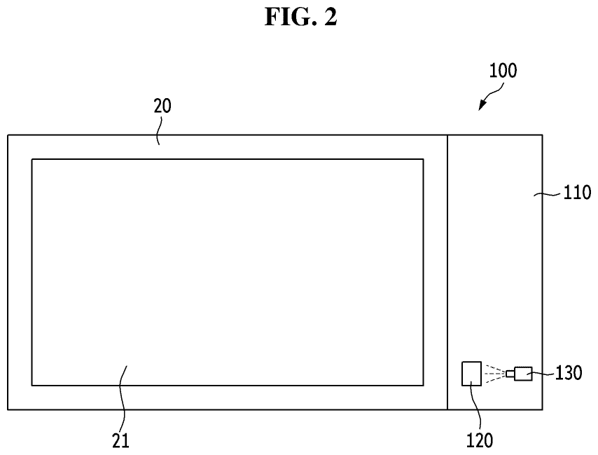

FIG. 1 is a perspective view of a manufacturing apparatus 1 for a display device according to an embodiment, and FIG. 2 is a top view illustrating a substrate 21, a stage 20, and a gap measurement unit 100 of FIG. 1.

Referring to FIGS. 1 and 2, the manufacturing apparatus 1 may include a base frame 10, the stage 20, a stage transfer unit, a dispenser 40, a dispenser support unit 50, a dispenser transfer unit, and the gap measurement unit 100. Here, first and second directions DR1 and DR2 are orthogonal directions on the same plane, and a third direction DR3 is perpendicular to both the first and second directions DR1 and DR2.

The base frame 10, which has a rectangular shape with its long sides aligned in the first direction and a predetermined thickness in the third direction DR3, may support the stage 20 and the stage transfer unit from below.

The stage 20 may be disposed on the base frame 10. The stage 20 may provide a space where a substrate 21 is disposed.

The substrate 21, which is the target object to be coated during an ejection process of the dispenser 40, may be seated on the upper surface of the stage 20. A substrate support unit (not illustrated) may be positioned on the stage 20 and may fix the position of the substrate 21 on the stage 20.

The stage 20 may include a substrate seating area B where the substrate 21 is positioned, and a surrounding area A where ink is discharged onto the substrate 21 by the dispenser 40.

The substrate seating area B is also an ejection process area where ink is discharged onto the substrate 21 during the ejection process, and may thus overlap with the substrate 21 during the ejection process.

The surrounding area A is positioned outside the ejection process area. The surrounding area A may be adjacent to the substrate seating area B and may not overlap with the substrate 21 during the ejection process.

The substrate seating area B and the surrounding area A may be formed on a single

stage body. For example, a substrate seating section may be provided in the central area of a single stage body to define the substrate seating area B, and the surrounding area A may be defined in a predetermined space outside the substrate seating section.

In some embodiments, the stage 20 may include a stage body that includes the substrate seating area B and an auxiliary frame that constitutes at least part of the surrounding area A, and the auxiliary frame may be coupled to one side of the stage body.

An example where the stage 20 includes the stage body and the auxiliary frame, where the auxiliary frame corresponds to a support frame 110 of the gap measurement unit 100, and where a gap measurement process is performed on the support frame 110, will hereinafter be described, but the present disclosure is not limited thereto. The gap measurement process may also be performed on the outside of the substrate seating section on the stage body.

The stage 20 may have the same planar shape as the substrate 21. For example, the stage 20 may have a rectangular, square, polygonal, circular, or oval shape, and the present disclosure is not limited thereto. In an embodiment, the stage 20 may have a different shape from the substrate 21.

The stage 20 may be formed of a transparent or translucent material that can transmit light, or an opaque material that can reflect light.

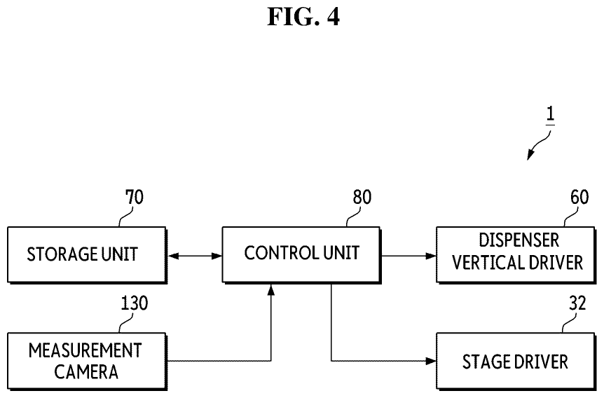

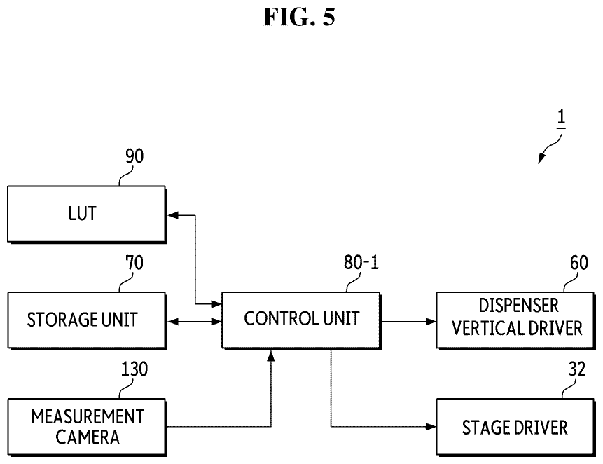

The stage transfer unit may be coupled to the stage 20 and may move the stage 20 along the first direction DR1. The stage transfer unit may include sliding rails 31 and a stage driver 32 (see FIGS. 4-5) that interacts with the sliding rails 31 to provide driving force for moving the stage 20.

The sliding rails 31 of the stage transfer unit are positioned on the base frame 10, may be coupled to the lower surface of the stage 20, and may be provided along the first direction DR1. The stage driver 32 may be, but is not limited to, a drive motor and may be any drive means capable of moving the stage 20. When the stage 20 moves, power is supplied to the stage driver 32, generating driving force, which moves the stage 20 along the sliding rails 31 in the first direction DR1. Thus, the stage 20 may reciprocate along the first direction DR1 between the substrate seating area B and the surrounding area A during the ejection process or a gap measurement process.

The dispenser support unit 50 may include a vertical support 51, a horizontal support 52, and a dispenser support 53, and may be coupled to one side of the base frame 10. For example, the dispenser support unit 50 may be fixedly coupled to the base frame 10, allowing it to perform processes while moving the stage 20. In an embodiment, the dispenser support unit 50 may be configured as a movable gantry, allowing it to perform processes while moving. However, the present disclosure is not limited to these examples.

The vertical support 51 of the dispenser support unit 50 may be fixedly or movably coupled to one side of the base frame 10.

The horizontal support 52 of the dispenser support unit 50 may be slidably coupled to the vertical support 51 along the third direction DR3, but the present disclosure is not limited thereto. In an embodiment, the horizontal support 52 may be fixedly coupled to the vertical support 51.

At least one dispenser 40 may be installed on the dispenser support 53 of the dispenser support unit 50. The dispenser support 53 may be fixedly or movably coupled to the horizontal support 52.

The dispenser transfer unit may include a dispenser vertical transfer portion that moves the dispenser 40 in the third direction DR3, which is a vertical direction.

The dispenser vertical transfer portion may be coupled to the dispenser support unit 50 where the dispenser 40 is installed, and may thus move the dispenser support unit 50 along the third direction DR3. The dispenser vertical transfer portion may include vertical sliding rails 54 and a dispenser vertical driver 60 (see FIGS. 4-5) that interacts with the vertical sliding rails 54 to provide driving force for moving the dispenser 40 in the third direction DR3.

Accordingly, the dispenser 40, installed on the dispenser support unit 50, may perform the ejection process by discharging the sealant onto the substrate 21 while being moved in the third direction DR3 by the dispenser vertical transfer portion. Specifically, as the horizontal support 52, the dispenser support 53, and the dispenser 40 are slidably coupled to the vertical sliding rails 54 of the vertical support 51, the horizontal support 52, and the dispenser support 53, respectively, the horizontal support 52 may adjust the distance between the dispenser 40 and the substrate 21 seated on the stage 20 by elevating the dispenser 40 vertically while moving vertically along the vertical sliding rails 54, in response to power being supplied to a stage vertical driver to supply driving force.

Here, the dispenser vertical transfer portion may include the vertical sliding rails 54, which are formed in the vertical direction, and a drive motor, or may include a hydraulic cylinder and a drive motor, but the present disclosure is not limited thereto. Various drive means capable of moving the dispenser 40 vertically may be applicable to the dispenser vertical transfer portion.

The vertical sliding rails 54 of the dispenser vertical transfer portion may be formed on the vertical support 51 of the dispenser support unit 50 and may guide the dispenser 40 to move in the direction indicated by a black unidirectional arrow.

The dispenser vertical driver 60 of the dispenser vertical transfer portion may be, but is not limited to, a drive motor. Various drive means capable of moving the dispenser 40 vertically may be applicable to the dispenser vertical driver 60.

Therefore, when there is a need to move the dispenser 40 vertically, power may be supplied to the dispenser vertical driver 60, which may be a drive motor, to generate driving force. This driving force may move the horizontal support 52 connected to the dispenser support 53, where the dispenser 40 is installed, along the vertical sliding rails 54 of the vertical support 51, and as a result, the dispenser 40 may move vertically, i.e., in the third direction DR3. Thus, the dispenser 40 may perform the ejection or gap measurement process while moving along the direction indicated by bidirectional arrows, i.e., in the third direction DR3.

The dispenser transfer unit has been described above as including the dispenser vertical transfer portion that moves the dispenser 40 in the third direction DR3. In some embodiments, the dispenser transfer unit may further include a dispenser horizontal transfer portion (not illustrated) that moves the dispenser 40 in the second direction DR2. For example, the dispenser horizontal transfer portion may include horizontal sliding rails (not illustrated), which are formed on the dispenser support 53, and to which the dispenser 40 is slidably coupled, and a horizontal drive motor that provides driving force to move the dispenser 40 along the horizontal sliding rails on the dispenser support 53.

Additionally, the dispenser 40 has been described above as moving in the third direction DR3 via the dispenser transfer unit, and the stage 20 has been described above as moving in the first direction DR1. That is, the relative positions of the dispenser 40 and the stage 20 may be changed by moving the stage 20 in the first direction DR1 with the dispenser 40 fixed in the first direction DR1. However, the present disclosure is not limited to this. In an embodiment, the relative positions of the dispenser 40 and the stage 20 may be changed by moving the dispenser 40 in the first direction DR1 with the stage 20 fixed, or by moving both the stage 20 and the dispenser 40 in the first direction DR1.

The dispenser 40 may discharge ink, and the ink may be provided in liquid form. However, the present disclosure is not limited to this.

In some embodiments, the ink may include, for example, a solvent and an organic material contained in the solvent. The organic material may be dispersed in the solvent. The organic material may be a solid substance that remains on a target substrate 21 after the solvent is removed. The solvent may be a substance that vaporizes or evaporates at room temperature or upon heating. The solvent may be acetone, water, alcohol, toluene, etc. The ink may be dissolved in the solvent or may be a suspended solid. Here, the solid may be an organic material, a metal material, etc. A sealant may be used as the ink, but the present disclosure is not limited thereto. Various types of ink mentioned above may also be used.

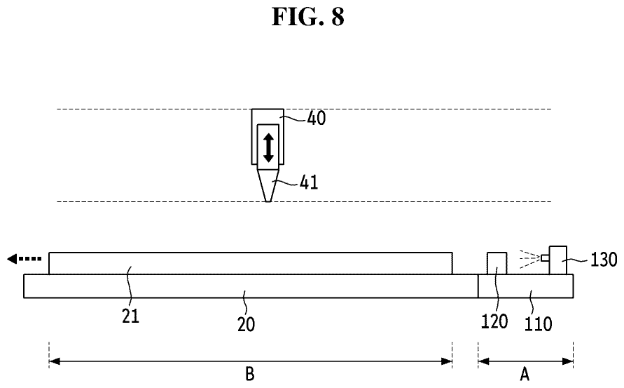

The dispenser 40 may eject, for example, a sealant, and may include the nozzle 41 (see FIGS. 8-18) that receives the sealant from a separate storage container (not illustrated) and discharges it onto the substrate 21. The sealant may be supplied from an external source to the nozzle 41 or may be supplied from an internal storage container within the dispenser 40 and discharged through the nozzle 41. The sealant may be an exemplary fluid ejected through the nozzle 41, but the present disclosure is not limited thereto. That is, a variety of other fluids such as liquid crystal or a solution for forming an organic film may also be used. Here, the dispenser 40 may be moved in a top-bottom direction by the dispenser transfer unit connected to the dispenser support unit 50, or may be installed to be movable in the top-bottom direction, i.e., in the third direction DR3, on the dispenser support 53. In an embodiment, a dispenser motor (not illustrated) may be provided separately to lift up or down the dispenser 40, or only the nozzle 41 may be lifted up or down.

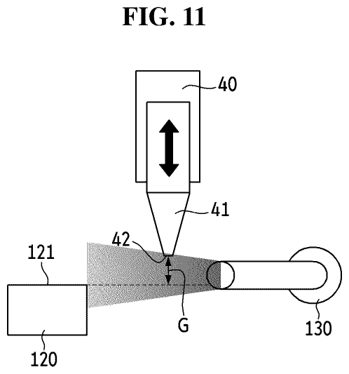

Referring still to FIGS. 1 and 2, the gap measurement unit 100 is positioned in a gap calibration area, which is the surrounding area A, on one side of the stage 20, i.e., on the movement path of the stage 20, and may calibrate a gap G (see FIG. 11) between the dispenser 40 and a reference block 120 that will be described later. Here, calibration means adjusting to a specific or set standard, and the calibration of the gap G may be performed before or during the ejection process that discharges the sealant onto the substrate 21.

The gap measurement unit 100 may include the support frame 110, which is fixed to one side of the base frame 10, the reference block 120, which is installed on the support frame 110, and a measurement camera 130, which is positioned adjacent to the reference block 120 and measures the gap G.

The support frame 110 may be integrally formed with the base frame 10 or may be provided as a separate frame to which the base frame 10 is coupled. Additionally, the support frame 110 may be fixed to the base frame 10 or may be installed to be lifted up or down in the third direction DR3 with respect to the base frame 10.

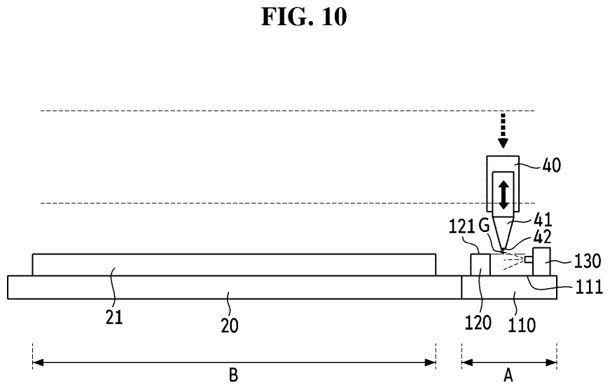

The support frame 110 may be positioned at an end portion of the base frame 10 along the first direction DR1, which is the movement direction of the stage 20. An upper surface 111 (see FIG. 10) of the support frame 110 may be positioned on the same plane as the upper surface of the base frame 10, such that the thickness of the support frame 110 in the third direction DR3 is the same as the thickness of the base frame 10 in the third direction DR3. However, the present disclosure is not limited to this. In an embodiment, the upper surface 111 of the support frame 110 and the upper surface of the base frame 10 may not be on the same plane, but positioned with a step difference. Additionally, the upper surface 111 of the support frame 110 may be positioned on the same plane as the upper surface of the stage 20, or the upper surface 111 of the support frame 110 and the upper surface of the stage 20 may be positioned with a step difference.

The reference block 120 may align a reference point, i.e., the zero point, so that the measurement camera 130 may measure the gap G. An upper surface 121 (see FIGS. 11-16) of the reference block 120 serves as a reference plane to allow the measurement camera 130 to measure the gap G.

The upper surface of the reference block 120 may form a flat plane along the first direction DR1, together with the upper surface of the substrate 21. In an embodiment, if the reference block 120 has a lower height than the substrate 21, the reference block 120 may be positioned with a step difference relative to the upper surface of the substrate 21.

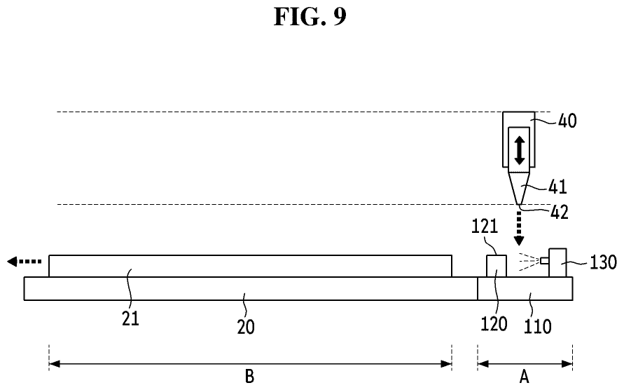

The measurement camera 130 is a means for measuring the gap G between the reference plane and a pointed tip 42 (see FIG. 9 for example), which is the end of the nozzle 41. To measure this gap, the height from the upper surface of the reference block 120 to the pointed tip 42 of the nozzle 41 may be measured using and zeroing the upper surface of the reference block 120 as the reference point. Additionally, the measurement camera 130 may further include a separate laser displacement sensor to measure the gap G along with the measurement camera 130. The laser displacement sensor may include a light-emitting part that outputs a distance-measuring laser toward the substrate 21 and a receiving part that receives the laser output from the light-emitting part, allowing for the measurement of the distance between the substrate 21 and the nozzle 41.

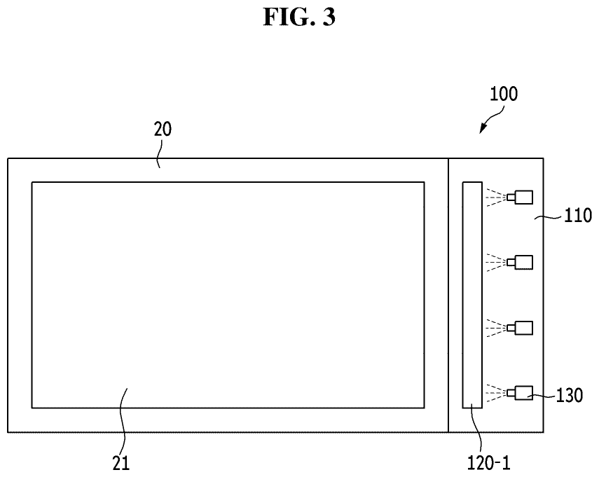

FIG. 3 is a top view of a manufacturing apparatus 1 for a display device according to an embodiment of the present disclosure.

The manufacturing apparatus 1 of FIG. 3 differs from its counterpart of FIG. 2 in that a gap measurement unit 100 includes a plurality of measurement cameras 130.

Unlike the gap measurement unit 100 of FIG. 2, which is equipped with one reference block 120 and one measurement camera 130, the gap measurement unit 100 of FIG. 3 may be equipped with a long bar-shaped reference block 120_1 and a plurality of measurement cameras 130 disposed along the length direction of the reference block 120_1, but the present disclosure is not limited thereto. In an embodiment, the gap measurement unit 100 may include a plurality of reference blocks 120 and a plurality of corresponding measurement cameras 130.

FIG. 4 is a block diagram of a manufacturing apparatus 1 for a display device according to an embodiment of the present disclosure.

Referring to FIG. 4, the manufacturing apparatus 1 may further include a storage unit 70 that stores a drive value of a dispenser vertical driver 60 based on gap measurement results from a measurement camera 130, and a control unit 80 that controls the dispenser vertical driver 60 to raise or lower a dispenser 40.

The storage unit 70 stores the drive value of the dispenser vertical driver 60. For example, if the dispenser vertical driver 60 is a drive motor, the dispenser vertical driver 60 may raise or lower the dispenser 40 under the control of the control unit 80, lifting the nozzle 41 of the dispenser 40 away from the substrate 21 or lowering the nozzle 41 toward the substrate 21. The storage unit 70 may store an encoder value from the drive motor, which is the dispenser vertical driver 60. This encoder value may be a position, angle, or speed measurement value, or a control value for the speed or amount of rotation of the drive motor.

The encoder value from the dispenser vertical driver 60 may be stored directly in the storage unit 70 based on the gap measurement results from the measurement camera 130.

When the dispenser 40 reaches the gap measurement unit 100, the control unit 80 may lower the dispenser 40 via the dispenser vertical driver 60, and may store the encoder value from the dispenser vertical driver 60 in the storage unit 70 based on the gap measurement results from the measurement camera 130.

The control unit 80 may store the drive value of the dispenser vertical driver 60 in the storage unit 70 if the gap measurement results indicate that the gap G matches a reference set value. The control unit 80 may move the dispenser 40 from a gap calibration area A to a substrate seating area B, which is an ejection area.

FIG. 5 is a block diagram of a manufacturing apparatus 1 for a display device according to an embodiment of the present disclosure.

Referring to FIG. 5, the manufacturing apparatus 1 may further include a storage unit 70 that stores a drive value of a dispenser vertical driver 60 based on gap measurement results from a measurement camera 130, a lookup table 90 that holds various drive values of the dispenser vertical driver 60 as data values, and a control unit 80-1 that controls the dispenser vertical driver 60 to raise or lower a dispenser 40.

The manufacturing apparatus 1 of FIG. 5 is the same as its counterpart of FIG. 4 except that it further includes the lookup table 90.

Specifically, an encoder value from the dispenser vertical driver 60 may be readily stored in the storage unit 70 depending on the gap measurement results from the measurement camera 130, as illustrated in FIG. 4. In an embodiment, as illustrated in FIG. 5, a separate lookup table may be additionally provided. Here, the lookup table 90, which is a table of frequently used data values, may include a drive value (i.e., an encoder value or data value) for the dispenser vertical driver 60 that corresponds to the gap measurement results.

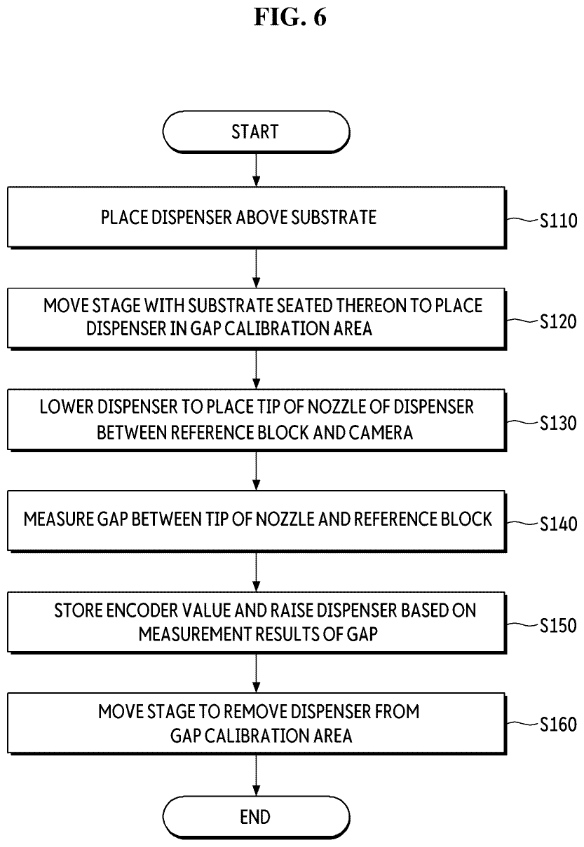

FIG. 6 is a flowchart illustrating a gap calibration method for a manufacturing apparatus 1 for a display device, according to an embodiment of the present disclosure.

Referring to FIG. 6, the gap calibration method includes: placing a dispenser 40 above a substrate 21 (S110); moving a stage 20 with the substrate 21 seated thereon to place the dispenser 40 in a gap calibration area A (S120); lowering the dispenser 40 to position a tip 42 of a nozzle 41 of the dispenser 40 between a reference block 120 and a measurement camera 130 (S130); measuring the gap between the tip 42 of the nozzle 41 and the reference block 120 (S140), if the measured gap matches a predetermined value, storing a corresponding encoder value and moving the dispenser 40 upward (S150); and moving the stage 20 to remove the dispenser 40 from the gap calibration area A (S160).

In this manner, if gap measurement results indicate that the measured gap matches a reference set value, the drive value of the dispenser vertical driver 60 may be stored in the storage unit 70, and the dispenser 40 may be readily moved from the gap calibration area A to an ejection area B.

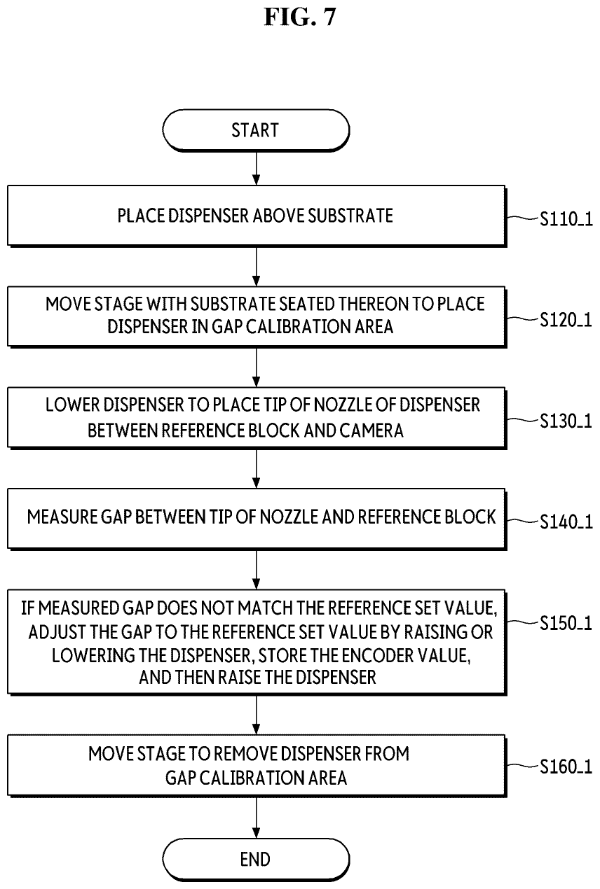

FIG. 7 is a flowchart illustrating a gap calibration method for a manufacturing apparatus 1 for a display device, according to an embodiment of the present disclosure.

Referring to FIG. 7, the gap calibration method includes: placing a dispenser 40 above a substrate 21 (S110_1); moving a stage 20 with the substrate 21 seated thereon to place the dispenser 40 in a gap calibration area A (S120_1); lowering the dispenser 40 to position a tip 42 of a nozzle 41 of the dispenser 40 between a reference block 120 and a measurement camera 130 (S130_1); measuring the gap between the tip 42 of the nozzle 41 and the reference block 120 (S140_1); if the measured gap does not match a predetermined value, adjusting the dispenser 40 to the predetermined value by raising or lowering the dispenser 40, storing a corresponding encoder value, and then moving the dispenser 40 upward (S150_1); and moving the stage 20 to remove the dispenser 40 from the gap calibration area A (S160_1).

In this manner, if gap measurement results indicate that the measured gap does not match the predetermined value, for example, if the measured gap is less than a reference set value, the dispenser 40 may be raised to adjust the gap, and if the measured gap is greater than the reference set value, the dispenser 40 may be lowered to adjust the gap. Thereafter, the encoder value may be stored, and the dispenser 40 may be moved out of the gap calibration area A.

The aforementioned gap calibration methods will hereinafter be described in further detail with reference to FIGS. 8 through 18.

FIGS. 8 through 14 illustrate a gap calibration process according to an embodiment of the present disclosure.

Referring to FIG. 8, with the dispenser 40 placed above the substrate 21, the stage 20 may be moved in the direction indicated by a unidirectional arrow from an initial position corresponding to the substrate seating area B. As a result, as illustrated in FIG. 9, the dispenser 40 may be positioned in the gap calibration area A, where the gap measurement unit 100 is positioned.

Referring to FIG. 9, when the dispenser 40 arrives at the gap calibration area A, the nozzle 41 of the dispenser 40 is positioned between the reference block 120 and the measurement camera 130.

Referring to FIG. 10, the nozzle 41 of the dispenser 40 may be positioned between the measurement camera 130 and the reference block 120 by lowering the dispenser 40 in the gap calibration area A, and the gap G may be measured.

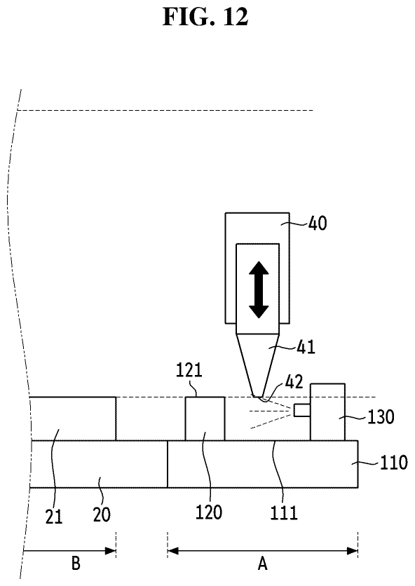

Referring to FIG. 11, if the gap G measured by the measurement camera 130 based on the upper surface 121 of the reference block 120 is the same as a previously set reference value, the control unit 80 may store a corresponding encoder value of a dispenser vertical driver 60 in a storage unit 70. For example, referring to FIG. 12, if the reference set value is zero and the measured gap is actually zero, meaning there is no gap between the reference block 120 and the dispenser 40, the encoder value of the dispenser vertical driver 60 that has lowered the dispenser 40 may be stored in the storage unit 70.

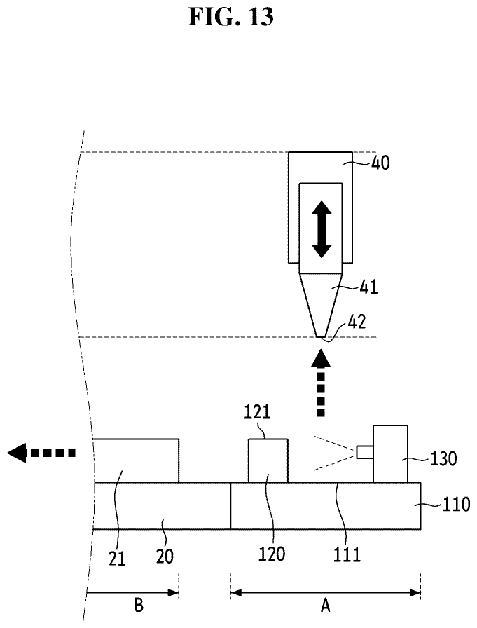

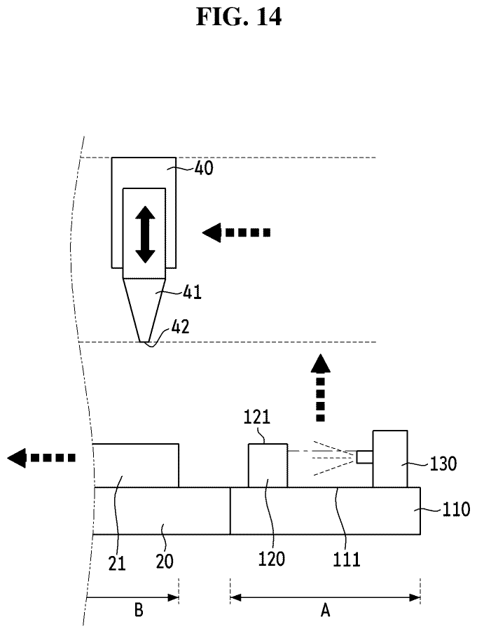

Referring to FIG. 13, the dispenser 40 may be raised by the dispenser vertical transfer portion. Referring to FIG. 14, the stage 20 may be moved by the stage transfer unit to remove the dispenser 40 from the gap calibration area A.

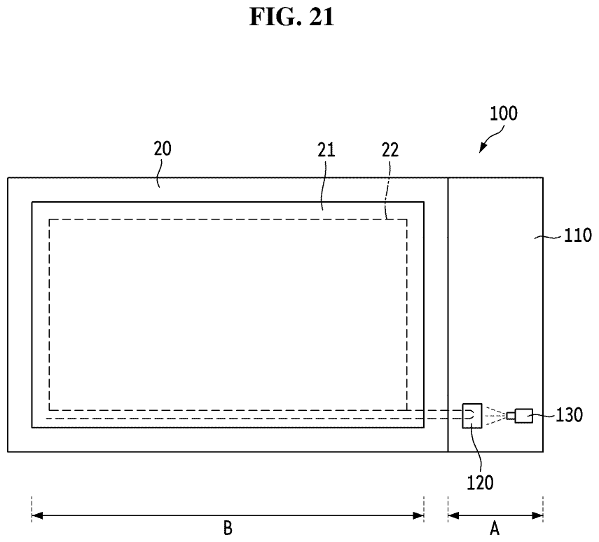

Referring to FIG. 21, the dispenser 40, which has exited the gap calibration area A, may discharge a sealant onto the substrate 21, applying the sealant along the edge areas of the substrate 21.

In this manner, since position correction for the dispenser 40 is conducted based on an accurately set gap value and the dispenser 40 is moved toward the substrate 21, the dispenser 40 can properly eject the sealant with its gap with the substrate 21 fixed, ensuring a stable discharge volume and consistent linewidth. Even if the dispenser 40 is raised to eject the sealant, the gap between the dispenser 40 and the substrate 21 can be precisely corrected, allowing the discharge volume of the sealant to be determined based on the stored encoder value during gap calibration.

In a touch-type gap measurement method, where the nozzle 41 directly contacts the surface of the substrate 21 to measure the gap therebetween, the nozzle 41 may have a free end, and thus, each contact angle may vary whenever the nozzle 41 touches the substrate 21, causing gap calibration errors and reducing the reproducibility of gap measurements. In contrast, in a non-contact gap calibration method according to an embodiment of the present disclosure, the gap measurement unit 100 is provided in a non-contact manner, thereby preventing changes in contact angle during measurement and avoiding damage to the nozzle 41. Also, accurate gap calibration allows for stable discharge volume settings are enabled, and precise linewidths can be provided based on accurate gap data.

Furthermore, since gap measurement can be performed in the gap calibration area A, which is a non-overlapping area with the substrate 21, gap measurement can be conducted not only before and after, but also during the ejection of ink onto the substrate 21. This allows gap measurement using the reference block 120 even when there is no substrate 21, and during the ejection of ink onto the substrate 21, gap measurement can be performed in the gap calibration area A beyond the ejection area on the substrate 21.

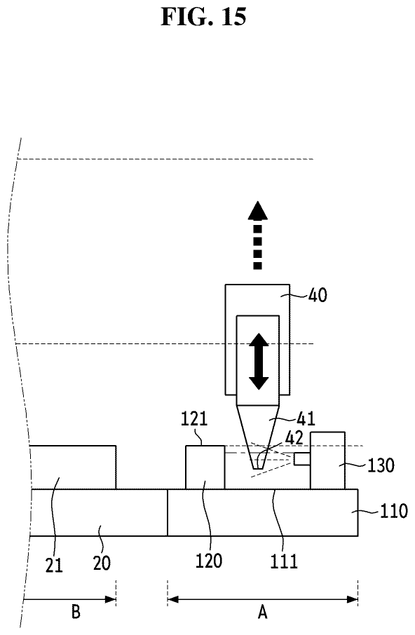

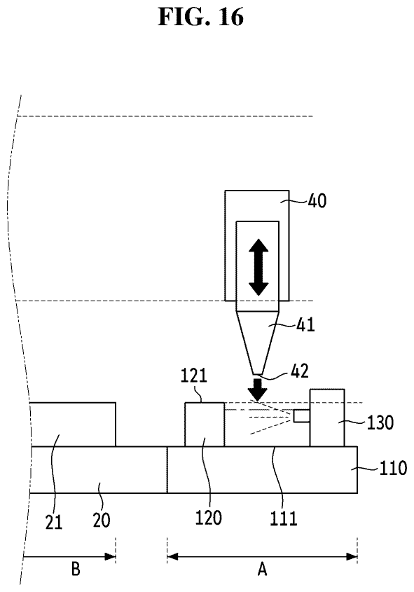

FIGS. 15 and 16 illustrate a gap calibration process according to an embodiment of the present disclosure.

The embodiment of FIGS. 15 and 16 is almost the same as the embodiment of FIGS. 8 through 14. Specifically, if the gap measured in the gap calibration area A deviates from a reference set value, particularly, if the measured gap is less than the reference set value, as illustrated in FIG. 15, the dispenser 40 may be raised to adjust the gap G to the reference set value. Conversely, if the measured value is greater than the reference set value, as illustrated in FIG. 16, the dispenser 40 may be lowered to adjust the gap G to the reference set value. Thereafter, the control unit 80 stores the corresponding encoder value of the dispenser vertical driver 60 in the storage unit 70, and the stage transfer unit moves the stage 20 to position the dispenser 40 out of the gap calibration area A.

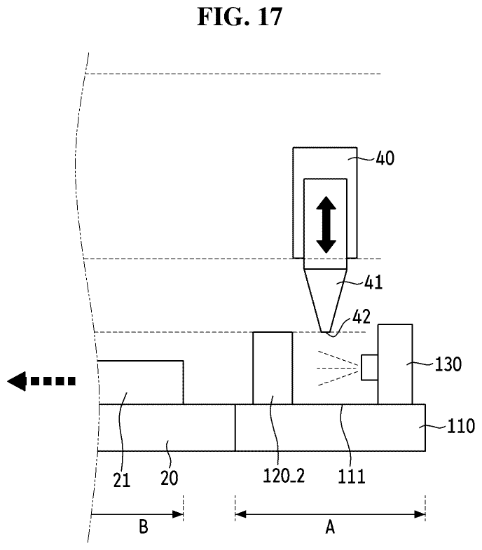

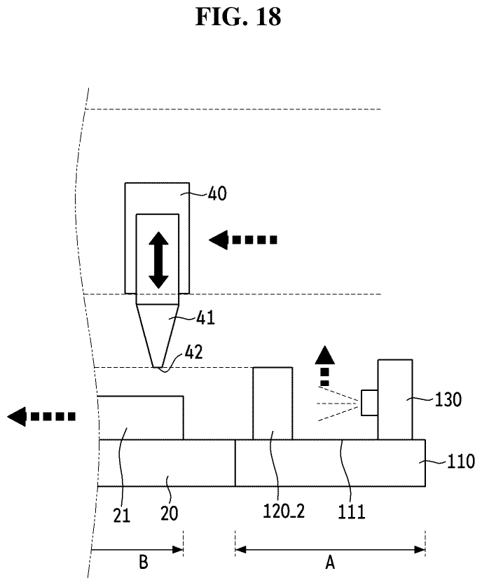

FIGS. 17 and 18 illustrate a gap calibration process according to an embodiment of the present disclosure.

The embodiment of FIGS. 17 and 18 is the same as the embodiment of FIGS. 8 through 14 except that the height from the upper surface 111 of the support frame 110 to the upper surface of a reference block 120_2 is greater than the height from the upper surface 111 of the support frame 110 to the upper surface of the substrate 21.

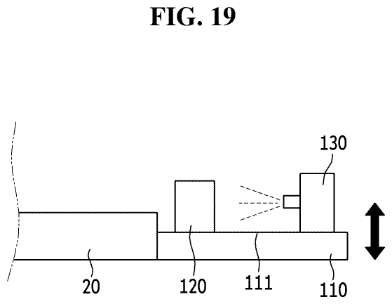

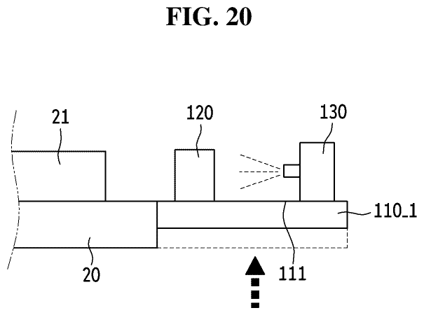

FIGS. 19 and 20 illustrate a gap calibration process according to an embodiment of the present disclosure.

The embodiment of FIGS. 19 and 20 is the same as the embodiment of FIGS. 8 through 14 except that the thickness of the support frame 110 is less than the thickness of the stage 20, as illustrated in FIG. 19, and that the support frame 110 is coupled to be adjustable in height relative to the stage 20. Here, a hydraulic cylinder and a motor may be provided as height adjustment means for coupling the support frame 110 to be adjustable in height, or sliding rails and receiving grooves for accommodating the sliding rails may be provided to allow sliding movement. However, the present disclosure is not limited to these examples.

Referring to FIGS. 19 and 20, when the substrate 21 is seated on the stage 20, a support frame 110_1 may be raised by the height adjustment means so that the upper surface of the substrate 21 and the upper surface of the reference block 120 may be on the same plane.

A display device manufactured by a manufacturing apparatus 1 for a display device according to an embodiment of the present disclosure will hereinafter be described.

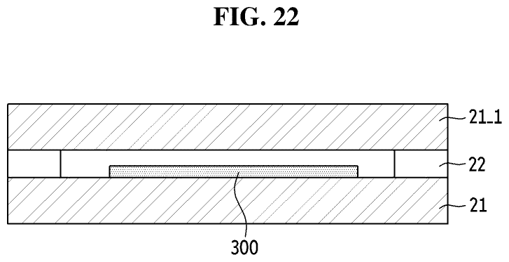

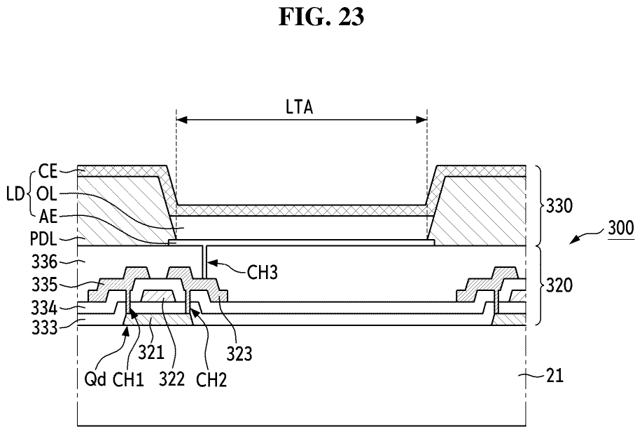

FIG. 21 is a top view illustrating the movement path between a gap calibration area A and an ejection area B, sometimes called a substrate seating area B, in a manufacturing apparatus 1 for a display device according to an embodiment of the present disclosure, FIG. 22 is a cross-sectional view of a display device manufactured by the manufacturing apparatus 1, and FIG. 23 is a cross-sectional view of a display panel of FIG. 22.

Referring to FIG. 21, a dispenser 40, positioned above a substrate 21, moves along the illustrated path to conduct gap measurement in the gap calibration area A where a gap measurement unit 100 is positioned. Thereafter, the dispenser 40 moves to the ejection area B to apply a sealant 22 onto the substrate 21 along the edges of the substrate 21 in the shape of a rectangular frame.

Referring to FIG. 22, with the sealant 22 applied in the shape of a rectangular frame on the substrate 21, another structure 21_1 is laminated on the substrate 21 to manufacture a display device that includes a display panel 300.

Referring to FIG. 23, the display panel 300 may include the substrate 21, a drive layer 320, a light-emitting element layer 330, and an encapsulation layer (not shown).

The substrate 21 provides space for the drive layer 320, the light-emitting element layer 330, and the encapsulation layer. The substrate 21 may be a flexible substrate formed of a polymer material with flexibility. For example, the substrate 21 may be formed of flexible plastics such as polyimide, polyethylene terephthalate, polyethylene naphthalate, polycarbonate, polyarylate, polyetherimide, polyethersulfone, etc. In an embodiment, the substrate 21 may be a rigid substrate such as a glass substrate, a semiconductor substrate, or a quartz substrate.

The drive layer 320 includes elements for providing signals to the light-emitting element layer 330. The drive layer 320 may include various signal lines, such as scan lines (not illustrated), data lines (not illustrated), power lines (not illustrated), and emission lines (not illustrated). The drive layer 320 may include a plurality of transistors and capacitors. The transistors may include a switching transistor (not illustrated) and a driving transistor Qd, which are provided in each pixel (not illustrated).

The driving transistor Qd includes an active layer 321, a gate electrode 322, a source electrode 335, and a drain electrode 323.

The drive layer 320 may further include a first insulating film 333, which is disposed on the active layer 321, and the gate electrode 322 may be positioned on the first insulating film 333.

The drive layer 320 may further include a second insulating film 334, which is positioned on the gate electrode 322. The source electrode 335 and the drain electrode 323 may be disposed on the second insulating film 334.

The source electrode 335 and the drain electrode 323 may be connected to the active layer 321 through contact holes CH1 and CH2, respectively, which are provided in the first and second insulating films 333 and 334. The source electrode 335 and the drain electrode 323 may be formed as metal multilayer structures of titanium (Ti)/aluminum (Al)/titanium (Ti), but the present disclosure is not limited thereto.

The drive layer 320 may further include a protective film 336, which is disposed on the source electrode 335 and the drain electrode 323.

The light-emitting element layer 330 may include a light-emitting element LD, and the light-emitting element LD may include a first electrode AE, an organic layer OL, and a second electrode CE.

The first electrode AE is disposed on the protective film 336. The first electrode AE is connected to the drain electrode 323 through a contact hole CH3, which is formed in the protective film 336.

The light-emitting element layer 330 may further include a pixel-defining layer PDL, which is disposed on the protective film 336. The pixel-defining layer PDL includes an opening that extends to and exposes the first electrode AE and may define an emission area LTA in plan view.

Thus, by conducting non-contact gap calibration before or during an ejection process, the accuracy of the discharge amount can be ensured, enabling the formation of a display device with a designated linewidth through a stable process.

In concluding the detailed description, those skilled in the art will appreciate that many variations and modifications can be made to the embodiments without substantially departing from the principles of the inventive concept. Therefore, the disclosed embodiments of the inventive concept are used in a generic and descriptive sense only and not for purposes of limitation.

What is claimed is:

1. A manufacturing apparatus for a display device, comprising:
a stage including a substrate seating area, which is configured for seating a substrate, and a surrounding area, which is positioned around the substrate seating area;
a dispenser positioned above the stage and including a nozzle for discharging ink; and
a gap measurement unit positioned at least partially in the surrounding area of the stage,
wherein the gap measurement unit includes a reference block and a camera that faces the reference block.

2. The manufacturing apparatus of claim 1, wherein
the stage includes:
a stage body, which includes the substrate seating area; and
an auxiliary frame, which is positioned on one side of the stage body, and
the gap measurement unit is disposed to overlap with the auxiliary frame.

3. The manufacturing apparatus of claim 1, wherein the reference block is positioned on a same plane as the substrate.

4. The manufacturing apparatus of claim 1, further comprising:
a dispenser vertical driver moving the dispenser vertically relative to the substrate and the reference block,
wherein in the surrounding area, the dispenser is raised or lowered vertically between the reference block and the camera by the dispenser vertical driver.

5. The manufacturing apparatus of claim 4, further comprising:
a storage unit storing a drive value of the dispenser vertical driver based on measurement results of a gap from the camera; and
a control unit controlling the dispenser vertical driver to raise and lower the dispenser.

6. The manufacturing apparatus of claim 5, wherein the measurement results indicate that the gap matches a reference set value, and the control unit stores the drive value of the dispenser vertical driver in the storage unit and moves the dispenser in the surrounding area to the substrate seating area.

7. The manufacturing apparatus of claim 5, further comprising:
a lookup table storing the drive value of the dispenser vertical driver as a data value.

8. The manufacturing apparatus of claim 2, further comprising:
height adjustment means coupling the auxiliary frame to be adjustable in height relative to the stage body.

9. The manufacturing apparatus of claim 2, wherein
the reference block is disposed on the auxiliary frame at a position apart from the substrate in a first direction, and
the camera is positioned behind the reference block in the first direction.

10. The manufacturing apparatus of claim 1, further comprising:
a base frame supporting the stage from below;
a stage transfer unit moving the stage along a first direction; and
a dispenser support unit coupling the dispenser to the base frame.

11. The manufacturing apparatus of claim 1, wherein
the reference block has a long bar shape along a second direction perpendicular to the first direction, and
a plurality of cameras including the camera are provided along the second direction.

12. A manufacturing method for a display device, comprising:
positioning a dispenser, including a nozzle, above a display device substrate seated on a stage;
moving the dispenser to a gap calibration area, which is positioned along a first direction away from the stage and in which a gap measurement unit with a reference block and a camera is positioned;
measuring a gap between an upper surface of the reference block and a tip of the nozzle in the gap calibration area using the camera; and
removing the dispenser from the gap calibration area when the gap matches a reference set value based on results of the measuring the gap.

13. The manufacturing method of claim 12, further comprising:
storing a drive value of a dispenser vertical driver, which moves the dispenser vertically relative to the substrate and the reference block, based on the results of the measuring the gap.

14. The manufacturing method of claim 13, wherein
the removing the dispenser comprises moving the dispenser from the gap calibration area to a discharge position above the substrate.

15. The manufacturing method of claim 14, further comprising:
ejecting a liquid onto the substrate at the discharge position while raising the dispenser based on the stored drive value.

16. The manufacturing method of claim 15, further comprising:
additionally measuring the gap during the ejecting the liquid; and
additionally storing a drive value of the dispenser vertical driver based on results of the additionally measuring the gap.

17. A manufacturing method for a display device, comprising:
positioning a dispenser, including a nozzle, above a display device substrate seated on a stage;
moving the dispenser to a gap calibration area, which is positioned along a first direction away from the stage and in which a gap measurement unit with a reference block and a camera is positioned;
measuring a gap between an upper surface of the reference block and a tip of the nozzle in the gap calibration area using the camera; and
calibrating the gap by raising or lowering the dispenser using a dispenser vertical driver based on results of the measuring the gap.

18. The manufacturing method of claim 17, further comprising:
storing a drive value of the dispenser vertical driver based on the results of the measuring the gap; and
moving the dispenser from the gap calibration area to a discharge position above the substrate.

19. The manufacturing method of claim 18, further comprising:
ejecting a liquid onto the substrate at the discharge position while raising the dispenser based on the stored drive value.

20. The manufacturing method of claim 19, wherein during the ejecting the liquid, the measuring the gap and the calibrating the gap are repeated at least once.
